(19) United States
(12) Patent Application Publication
(10) Pub. No.: US 2025/0201745 A1
(43) Pub. Date: Jun. 19, 2025

(54) SEMICONDUCTOR CHIP AND SEMICONDUCTOR PACKAGE INCLUDING THE SAME

(71) Applicant: SAMSUNG ELECTRONICS CO., LTD., Suwon-si (KR)

(72) Inventors: Yiyoung Kim, Suwon-si (KR); Subin Lee, Suwon-si (KR); Wonil Lee, Suwon-si (KR)

(73) Assignee: SAMSUNG ELECTRONICS CO., LTD., Suwon-si (KR)

(21) Appl. No.: 18/901,859

(22) Filed: Sep. 30, 2024

(30) Foreign Application Priority Data
Dec. 14, 2023 (KR) 10-2023-0182372

(51) Int. Cl. H01L 23/00; H01L 23/48; H01L 25/18; H10B 80/00

(52) U.S. Cl. CPC H01L 24/06; H01L 23/481; H01L 24/05; H01L 24/08; H01L 25/18; H10B 80/00; H01L 2224/05553; H01L 2224/05555; H01L 2224/05647; H01L 2224/0603; H01L 2224/06051; H01L 2224/06181; H01L 2224/08146

(57) ABSTRACT

A semiconductor chip includes a semiconductor substrate, a plurality of through vias passing through at least a portion of the semiconductor substrate, and a plurality of upper pads contacting the plurality of through vias, wherein, in a plan view, each of the plurality of upper pads surrounds a respective one of the plurality of through vias, and at least one of the plurality of upper pads has a tetragonal cross-sectional shape.

### CROSS-REFERENCE TO RELATED APPLICATION

This application is based on and claims priority under 35 U.S.C. § 119 to Korean Patent Application No. 10-2023-0182372, filed on Dec. 14, 2023, in the Korean Intellectual Property Office, the disclosure of which is incorporated by reference herein in its entirety.

### BACKGROUND

The present disclosure relates to a semiconductor chip and a semiconductor package including the same, and more particularly, to a semiconductor chip including a through via and a pad and a semiconductor package including the semiconductor chip.

As small sized, large capacity, and high-performance electronic products are needed, there is a need to increase the degree of integration and the speed of semiconductor packages. To this end, semiconductor packages including a plurality of semiconductor chips including stacked semiconductor chips and a method of manufacturing a semiconductor package have been developed.

### SUMMARY

Example embodiments of the present disclosure provide a semiconductor chip that may have enhanced reliability and a semiconductor package including the semiconductor chip.

Aspects of embodiments of the present disclosure are not limited to the aforesaid, and other aspects will be clearly understood by those of ordinary skill in the art from descriptions below.

According to an aspect of the present disclosure, a semiconductor chip is provided and includes: a semiconductor substrate; a plurality of through vias passing through at least a portion of the semiconductor substrate; and a plurality of upper pads contacting the plurality of through vias, wherein, in a plan view, each of the plurality of upper pads surround a respective one of the plurality of through vias, and wherein at least one of the plurality of upper pads has a tetragonal cross-sectional shape.

According to an aspect of the present disclosure, a semiconductor chip is provided and includes: a semiconductor substrate; an upper insulation layer on an upper surface of the semiconductor substrate; a lower insulation layer on a lower surface of the semiconductor substrate; a plurality of through vias passing through at least a portion of the semiconductor substrate and the upper insulation layer; and a plurality of upper pads surrounded by the upper insulation layer and contacting the plurality of through vias, wherein, in a plan view, each of the plurality of upper pads surrounds a respective one of the plurality of through vias, wherein the plurality of upper pads include a first pad and a second pad, and wherein the second pad has a tetragonal cross-sectional shape.

According to an aspect of the present disclosure, a semiconductor package is provided and includes: a high bandwidth memory (HBM) control die having a first horizontal width and including a first semiconductor substrate including an active surface and an inactive surface that are opposite to each other, and a plurality of through vias passing through at least a portion of the first semiconductor substrate; a plurality of dynamic random-access memory (DRAM) dies each having a second horizontal width less than the first horizontal width and including a second semiconductor substrate including an active surface and an inactive surface that are opposite to each other, the active surface of the second semiconductor substrate being stacked on the HBM control die such and facing the inactive surface of the first semiconductor substrate; a plurality of coupling pads between the HBM control die and the plurality of DRAM dies; a chip coupling insulation layer between the HBM control die and the plurality of DRAM dies to surround the plurality of coupling pads; and a package molding layer on an upper surface of the HBM control die and side surfaces of the plurality of DRAM dies, wherein the plurality of coupling pads includes a first coupling pad and a second coupling pad, and the second coupling pad has a tetragonal cross-sectional shape.

### BRIEF DESCRIPTION OF THE DRAWINGS

The above and/or other aspects will be more clearly understood from the following detailed description taken in conjunction with the accompanying drawings, in which:

FIG. 1 is a cross-sectional view illustrating a semiconductor chip according to an embodiment;

FIG. 2 is a plan view illustrating a semiconductor chip according to an embodiment;

FIG. 3 is an enlarged plan view of a region III of FIG. 2;

FIG. 4 is an enlarged plan view of a region IV of FIG. 2;

FIG. 5 is a plan view illustrating an arrangement of a through via, a first pad, and a second pad according to an embodiment;

FIG. 6 is a plan view illustrating an arrangement of a through via and a second pad according to an embodiment;

FIG. 7 is a cross-sectional view illustrating an operation of a method of forming an upper pad, according to an embodiment;

FIG. 8 is a cross-sectional view illustrating an operation of the method of forming the upper pad, according to the embodiment;

FIG. 9 is a cross-sectional view illustrating an operation of the method of forming the upper pad, according to the embodiment;

FIG. 10 is a cross-sectional view illustrating an operation of the method of forming the upper pad, according to the embodiment; and

FIG. 11 is a cross-sectional view illustrating a semiconductor package according to an embodiment.

### DETAILED DESCRIPTION

Hereinafter, non-limiting example embodiments of the present disclosure will be described in detail with reference to the accompanying drawings. Like reference numerals refer to like elements in the drawings, and repeated descriptions thereof may be omitted. In the drawings, the thickness or size of each layer may be exaggerated for convenience of description and clarity, and thus, may slightly differ from a real shape and ratio.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

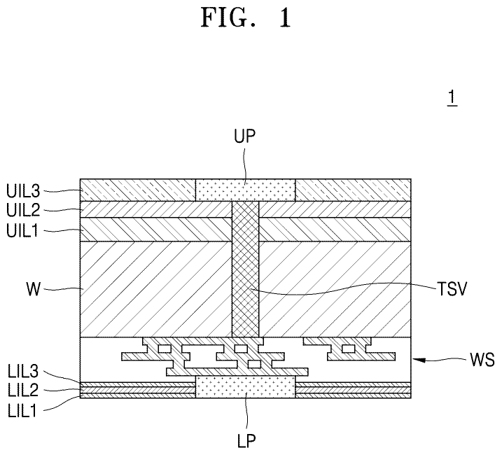

FIG. 1 is a cross-sectional view illustrating a semiconductor chip 1 according to an embodiment.

Referring to FIG. 1, the semiconductor chip 1 may include a semiconductor substrate W, a through via TSV, a plurality of upper insulation layers (e.g., a first upper insulation layer UIL1, a second upper insulation layer UIL2, and a third upper insulation layer UIL3), an upper pad UP, an interlayer insulation layer, a wiring structure WS, a plurality of lower insulation layers (e.g., a first lower insulation layer LIL1, a second lower insulation layer LIL2, and a third lower insulation layer LIL3), and a lower pad LP.

Herein, a direction parallel to a main surface of the semiconductor chip 1 may be defined as a horizontal direction (an X direction and/or a Y direction), and a direction perpendicular to the horizontal direction (the X direction and/or the Y direction) may be defined as a vertical direction (a Z direction).

The semiconductor chip 1 may include a logic semiconductor chip and/or a memory semiconductor chip. For example, the semiconductor chip 1 may include a central processing unit (CPU), a micro processing unit (MPU), a graphics processing unit (GPU), or an application processor (AP). For example, the semiconductor chip 1 may include, for example, a volatile memory semiconductor chip, such as dynamic random-access memory (DRAM) or static random-access memory (SRAM), or a non-volatile memory semiconductor chip such as phase-change random access memory (PRAM), magnetoresistive random access memory (MRAM), ferroelectric random-access memory (FeRAM), or resistive random-access memory (RRAM).

The semiconductor substrate W may include an active surface and an inactive surface, which are opposite to each other. A semiconductor device and the wiring structure WS may be formed on the active surface of the semiconductor substrate W. The through via TSV formed to pass through at least a portion of the semiconductor substrate W in a vertical direction (a Z direction) may be disposed in the semiconductor substrate W. The through via TSV may provide a path in the semiconductor chip 1 through which an electrical signal is transferred. Also, the through via TSV may provide a path in the semiconductor chip 1 through which heat is transferred.

A plurality of upper insulation layers (e.g., the first upper insulation layer UIL1, the second upper insulation layer UIL2, and the third upper insulation layer UIL3) and the upper pad UP may be disposed on an upper surface of the semiconductor substrate W. The through via TSV may pass through the first upper insulation layer UIL1 and the second upper insulation layer UIL2 in the vertical direction (the Z direction), and the upper pad UP may be disposed on the through via TSV.

The wiring structure WS may include a plurality of wiring patterns which extend a horizontal direction (an X direction and/or a Y direction), a plurality of wiring vias which electrically connect the plurality of wiring patterns with each other, and an interlayer insulation layer which surrounds the plurality of wiring patterns and the plurality of wiring vias. The plurality of wiring patterns and the plurality of wiring vias may be electrically connected to the through via TSV.

The plurality of lower insulation layers (e.g., the first lower insulation layer LIL1, the second lower insulation layer LIL2, and the third lower insulation layer LIL3) may be formed on a lower surface of the interlayer insulation layer, and the lower pad LP passing through at least a portion of each of the plurality of lower insulation layers (e.g., the first lower insulation layer LIL1, the second lower insulation layer LIL2, and the third lower insulation layer LIL3) in the vertical direction (the Z direction) may be formed thereon. The lower pad LP may pass through at least a portion of the interlayer insulation layer in the vertical direction (the Z direction). The lower pad LP may contact at least one of the plurality of wiring patterns. The lower pad LP may be electrically connected to at least one of the plurality of wiring patterns.

In FIG. 1, it is illustrated that the upper insulation layers and the lower insulation layers are each configured with three layers, but embodiments of the present disclosure are not limited thereto. The upper insulation layers and the lower insulation layers may include a various number of layers.

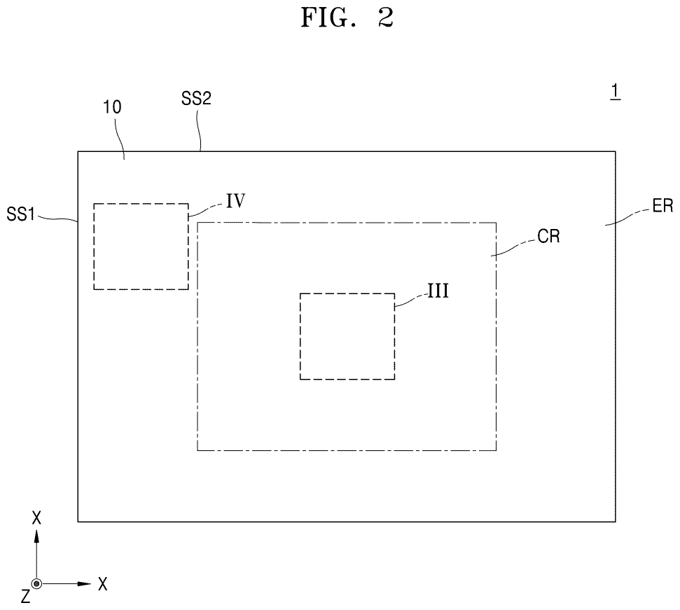

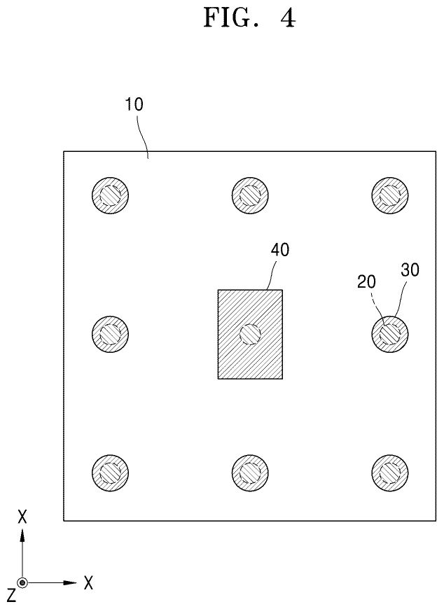

In a case where a plurality of semiconductor chips 1 are stacked in the vertical direction (the Z direction), an upper pad UP of a lower one of the semiconductor chips 1 may be bonded to a lower pad LP of an upper one of the semiconductor chips 1. An embodiment where a first pad 30 (see FIG. 4) and a second pad 40 (see FIG. 4) are formed for increasing overlay measurement accuracy of the upper pad UP will be described with reference to FIGS. 2 to 10.

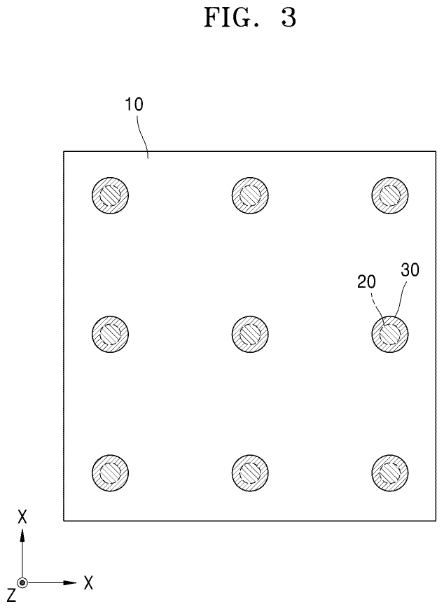

FIG. 2 is a plan view illustrating a semiconductor chip 1 according to an embodiment. FIG. 3 is an enlarged plan view of a region III of FIG. 2, and FIG. 4 is an enlarged plan view of a region IV of FIG. 2. For convenience of description, the through via 20, the first pad 30, and the second pad 40 may be omitted in FIG. 2.

Referring to FIGS. 2 to 4, the semiconductor chip 1 may include a semiconductor substrate 10, through vias 20, first pads 30, and second pads 40. The semiconductor chip 1 may include a first sidewall SS1 extending in a first horizontal direction (an X direction) and a second sidewall SS2 extending in a second horizontal direction (a Y direction). Also, the semiconductor substrate 10 may include a sidewall extending in the first horizontal direction (the X direction) and a sidewall extending in the second horizontal direction (the Y direction).

In a plane view, each of a plurality of the through vias 20 may have a circular cross-sectional shape. In a plan view, the plurality of through vias 20 may be arranged on the semiconductor substrate 10 to have a lattice array.

The first pad 30 or the second pad 40 may be disposed on an upper surface of each of the plurality of through vias 20. Each of the plurality of through vias 20 may contact the first pad 30 or the second pad 40. The first pad 30 may provide a path through which the semiconductor chip 1 is electrically connected to a different element (e.g., a semiconductor chip 1 and/or an interposer). The second pad 40 may function as a criterion which determines whether the first pad 30 is normally formed. The second pad 40 may be a pad for overlay measurement on the first pad 30.

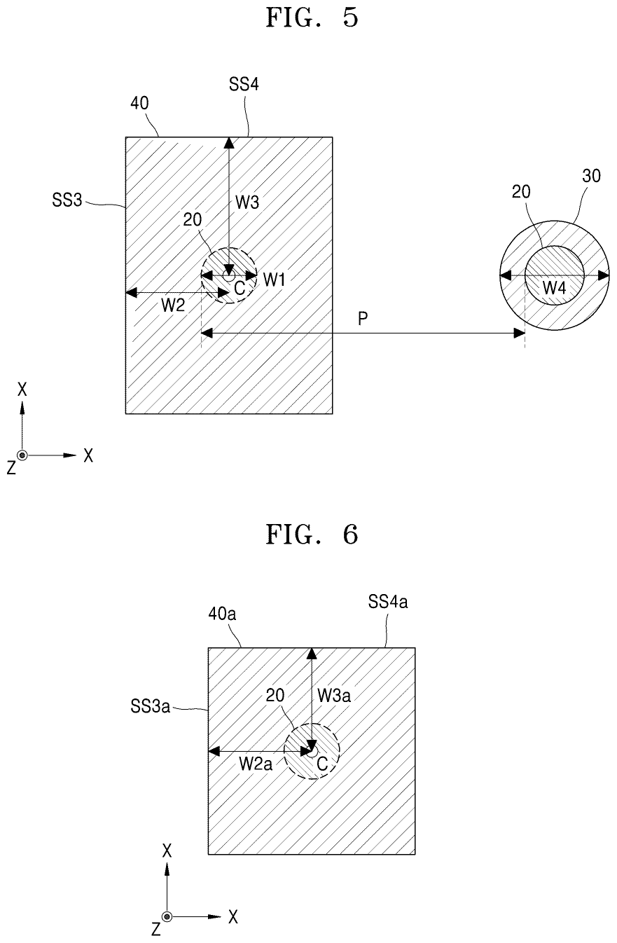

The second pad 40 may include a third sidewall SS3 (see FIGS. 5-6) extending in the first horizontal direction (the X direction) and a fourth sidewall SS4 (see FIGS. 5-6) extending in the second horizontal direction (the Y direction). The third sidewall SS3 of the second pad 40 may extend in the same direction as the first sidewall SS1 of the semiconductor chip 1, and the fourth sidewall SS of the second pad 40 may extend in the same direction as the second sidewall SS2 of the semiconductor chip 1.

The first pad 30 may be disposed in a center region CR and an edge region ER of the semiconductor chip 1, and the second pad 40 may be disposed in the edge region ER of the semiconductor chip 1. In other embodiments, the second pad 40 may be disposed in the center region CR of the semiconductor chip 1. FIG. 3 illustrates an example embodiment of the arrangement of the first pad 30 and the second pad 40 in the center region CR, and FIG. 4 illustrates an example embodiment of the arrangement of the first pad 30 and the second pad 40 in the edge region ER. In a plan view, the edge region ER may surround the center region CR.

In FIG. 3, it is illustrated that the second pad 40 is disposed adjacent to a left upper end of the semiconductor chip 1, but embodiments of the present disclosure are not limited thereto. For example, the second pad 40 may be disposed at a right upper end, a right lower end, and/or a left lower end of the semiconductor chip 1.

In a plan view, the first pad 30 and the second pad 40 may have different shapes. For example, in a plan view, the first pad 30 may have a circular shape, and the second pad 40 may have a tetragonal shape. For example, in a plan view, the second pad 40 may have a rectangular shape.

In a plan view, each of the first pad 30 and the second pad 40 may surround each of the plurality of through vias 20. A cross-sectional area of each of the plurality of through vias 20 may be less than a cross-sectional area of each of the first pad 30 and the second pad 40. A size of a cross-sectional area of the first pad 30 may be less than that of a cross-sectional area of the second pad 40.

The second pad 40 may contact a through via 20 that is a signal through via and/or a dummy through via. In other embodiments, the second pad 40 may contact the dummy through via.

Each of the first pad 30 and the second pad 40 may include the same material. In other embodiments, the first pad 30 and the second pad 40 may include different materials. For example, the first pad 30 and the second pad 40 may include copper (Cu).

The semiconductor chip 1 according to an embodiment may include the second pad 40 having a rectangular shape. Particularly, each of a plurality of sidewalls of the second pad 40 may extend in the same direction as each of a plurality of sidewalls of the semiconductor chip 1. The second pad 40 may be a pad for overlay measurement on the first pad 30, and whether the first pad 30 is defective may be determined by measuring the second pad 40.

FIG. 5 is a plan view illustrating the arrangement of a through via, a first pad, and a second pad according to an embodiment. FIG. 5 may be described with reference to FIGS. 1 to 4. In FIG. 5, only one first pad 30 and one second pad 40 are illustrated.

Referring to FIG. 5, a second pad 40 may have a rectangular shape. As described above, the second pad 40 may include a third sidewall SS3 extending in a first horizontal direction (an X direction) and a fourth sidewall SS4 extending in a second horizontal direction (a Y direction).

In a plan view, the second pad 40 may surround a through via 20. The through via 20 may have a first width W1 in a horizontal direction (the X direction and/or the Y direction). The first width W1 may correspond to a critical dimension (CD) of the through via 20. A range of the first width W1 may be, for example, about 2 μm to about 10 μm.

The third sidewall SS3 of the second pad 40 may be apart from the through via 20 in the second horizontal direction (the Y direction). The second pad 40 may have a second width W2 that is a distance from the third sidewall SS3 of the second pad 40 to the center C of the through via 20. The second width W2 may be greater than the first width W1. For example, the second width W2 may be about 1.5 or more times the first width W1. For example, the second width W2 may be about 1.8 or more times the first width W1. For example, a range of the second width W2 may be, for example, about 3 μm to about 20 μm.

The fourth sidewall SS4 of the second pad 40 may be apart from the through via 20 in the first horizontal direction (the X direction). The second pad 40 may have a third width W3 that is a distance from the fourth sidewall SS4 of the second pad 40 to the center C of the through via 20. The third width W3 may be greater than the first width W1. For example, the third width W3 may be about 1.5 or more times the first width W1. For example, the third width W3 may be about 1.8 or more times the first width W1. For example, a range of the third width W3 may be, for example, about 3 μm to about 20 μm.

As described above, the second pad 40 may have a rectangular shape, and the second width W2 may differ from the third width W3. In FIG. 5, it is illustrated that the third width W3 is greater than the second width W2, but embodiments of the present disclosure are not limited thereto. For example, according to an embodiment, the third width W3 may be less than the second width W2.

In a case where each of the second width W2 and/or the third width W3 increases compared to the first width W1, the recognition of overlay measurement for measuring the second pad 40 may increase. Accordingly, each of the second width W2 and/or the third width W3 may be about 1.5 or more times the first width W1. For example, in a case where at least one of the second width W2 and/or the third width W3 is about 1.5 or more times the first width W1, distortion may occur in a sidewall of the second pad 40.

Also, the first pad 30 may have a fourth width W4 in the horizontal direction (the X direction and/or the Y direction). The fourth width W4 may correspond to a critical dimension of the first pad 30. The fourth width W4 may be within a range of about 1.5 to about 2.5 times the first width W1.

Also, a pitch P between through vias 20 may be about 2 or more times the first width W1.

FIG. 6 is a plan view illustrating the arrangement of a through via and a second pad 40a according to an embodiment. FIG. 6 may be described with reference to FIGS. 1 to 5. In FIG. 6, for example, only one second pad 40a is illustrated.

Referring to FIG. 6, a second pad 40a may have a square shape. The second pad 40a may include a third sidewall SS3a extending in a first horizontal direction (an X direction) and a fourth sidewall SS4a extending in a second horizontal direction (a Y direction).

In a plan view, the second pad 40a may surround a through via 20. The third sidewall SS3a of the second pad 40a may be apart from the through via 20 in the second horizontal direction (the Y direction). The second pad 40a may have a second width W2a that is a distance from the third sidewall SS3a of the second pad 40a to the center C of the through via 20. The second width W2a may be greater than a first width W1 (see FIG. 5). For example, the second width W2a may be about 1.5 or more times the first width W1. For example, the second width W2a may be about 1.8 or more times the first width W1. For example, a range of the second width W2a may be, for example, about 3 μm to about 20 μm.

The fourth sidewall SS4a of the second pad 40a may be apart from the through via 20 in the first horizontal direction (the X direction). The second pad 40a may have a third width W3a that is a distance from the fourth sidewall SS4a of the second pad 40a to the center C of the through via 20. The third width W3a may be greater than the first width W1 (see FIG. 5). For example, the third width W3a may be about 1.5 or more times the first width W1. For example, the third width W3a may be about 1.8 or more times the first width W1. For example, a range of the third width W3a may be, for example, about 3 μm to about 20 μm. As described above, the second pad 40a may have a square shape, and the second width W2a may be the same as the third width W3a.

FIGS. 7 to 10 are cross-sectional views illustrating a method of forming at least one upper pad, according to an embodiment. FIGS. 7 to 10 may be described with reference to FIGS. 1 to 6. In FIGS. 7 to 10, for convenience of description, only a semiconductor substrate W, an upper insulation layer(s), a through via TSV, and an upper pad UP of a semiconductor chip 1 are illustrated.

Referring to FIG. 7, a first insulation layer IL1 and a second insulation layer IL2 may be formed on the semiconductor substrate W. Also, at least one through via TSV passing through at least a portion of the semiconductor substrate W in a vertical direction (a Z direction) may be formed. The first insulation layer IL1 and the second insulation layer IL2 may surround the at least one through via TSV. In more detail, after the semiconductor substrate W is prepared, the at least one through via TSV passing through at least a portion of the semiconductor substrate W in the vertical direction (the Z direction) may be formed. Subsequently, by grinding one surface of the semiconductor substrate W, at least a portion of the at least one through via TSV may protrude from the one surface of the semiconductor substrate W. For example, in FIG. 7, at least a portion of the at least one through via TSV may protrude from an upper surface of the semiconductor substrate W. Subsequently, the first insulation layer IL1 and the second insulation layer IL2 may be formed to surround the at least one through via TSV, on the semiconductor substrate W. An upper surface of the second insulation layer IL2 and an upper surface of the at least one through via TSV may be disposed at the same vertical level.

Each of the first insulation layer IL1 and the second insulation layer IL2 may include an insulating material. For example, the first insulation layer IL1 may include oxide, and the second insulation layer IL2 may include nitride.

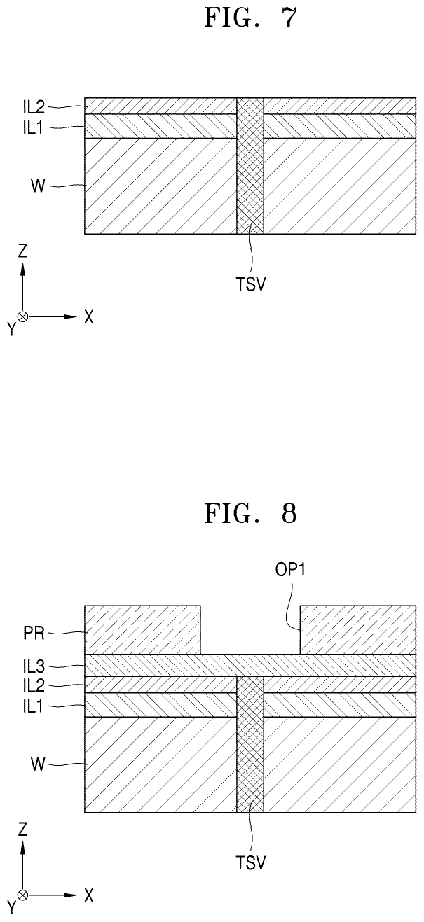

Referring to FIG. 8, a third insulation layer IL3 and a photoresist pattern PR may be formed on the second insulation layer IL2 and the at least one through via TSV. The photoresist pattern PR may include at least one first opening OP1. The at least one first opening OP1 may overlap the at least one through via TSV in the vertical direction (the Z direction). Each of the at least one first opening OP1 may be formed to overlap a position, at which a first pad 30 or a second pad 40 (see FIGS. 3-6) is to be formed subsequently, in the vertical direction (the Z direction).

For example, the third insulation layer IL3 may include oxide. The first insulation layer IL1, the second insulation layer IL2, and the third insulation layer IL3 may each function as a passivation layer of a semiconductor chip subsequently.

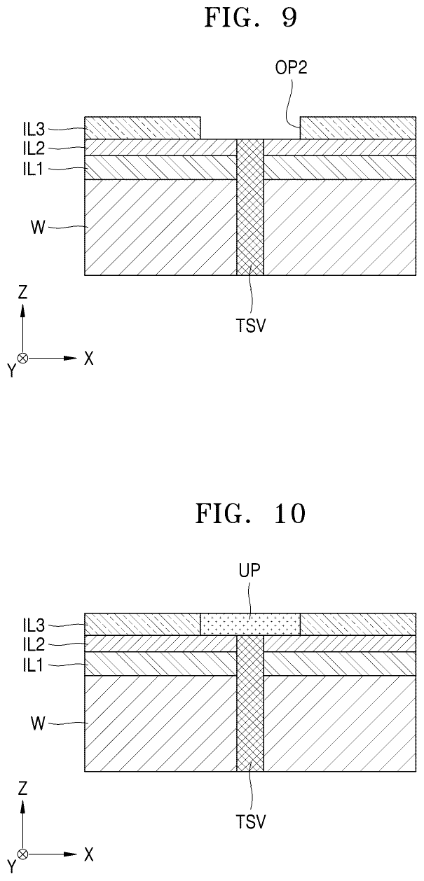

Referring to FIG. 9, by using the photoresist pattern PR of FIG. 8, the third insulation layer IL3 may be etched. Subsequently, the photoresist pattern PR of FIG. 8 may be removed. The photoresist pattern PR of FIG. 8 may be removed by a strip/ashing process.

Also, as the third insulation layer IL3 is etched, at least one second opening OP2 may be formed. The at least one second opening OP2 may overlap the at least one through via TSV in the vertical direction (the Z direction). Each of the at least one second opening OP2 may be formed at a position at which a first pad 30 or a second pad 40 is to be formed subsequently.

For example, after a photo process is performed, overlay measurement may be performed on the semiconductor chip 1. For example, by measuring the first opening OP1 of FIG. 8 and/or the second opening OP2, that corresponds to a second pad (e.g., second pad 40 or second pad 40a to be formed), measurement on the first pad 30 may be performed.

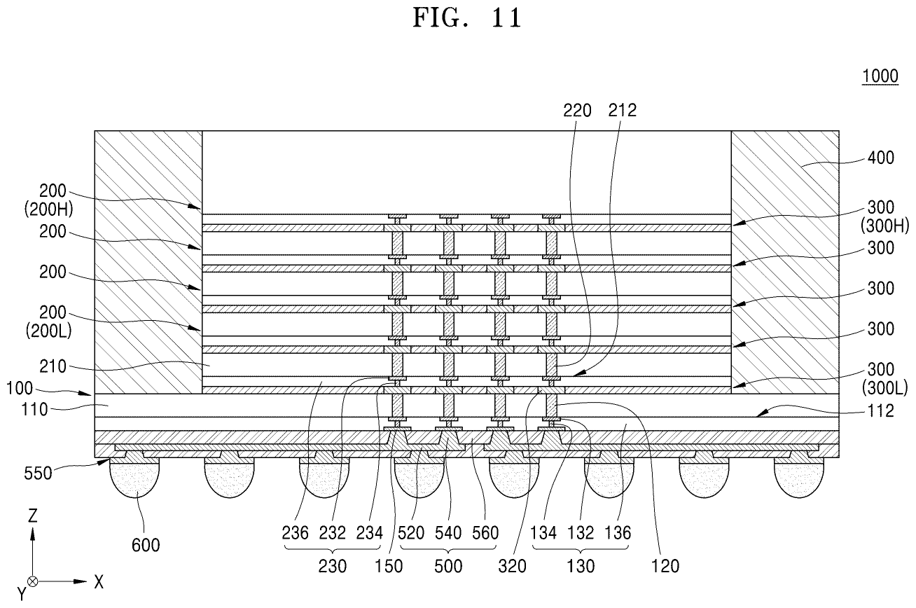

Referring to FIG. 10, a metal material may be formed on the at least one second opening OP2 of FIG. 9, and at least one upper pad UP may be formed by a chemical mechanical polishing (CMP) process. For example, the metal material may be formed on the at least one second opening OP2 by using an electro-plating process. As described above, a plurality of the upper pad UP may include at least one first pad 30 and at least one second pad 40, respectively.

A lower surface of the at least one upper pad UP may contact the at least one through via TSV. An upper surface of the at least one upper pad UP may be disposed at the same vertical level as an upper surface of the third insulation layer IL3. According to embodiments, a shape of a cross-sectional surface of the at least one first pad 30 may differ from a shape of a cross-sectional surface of the at least one second pad 40, and dimensions of the at least one first pad 30 and the at least one second pad 40 may differ.

FIG. 11 is a cross-sectional view illustrating a semiconductor package 1000 according to an embodiment. FIG. 11 may be described with reference to FIGS. 1 to 10.

Referring to FIG. 11, the semiconductor package 1000 may include a first semiconductor chip 100 and at least one second semiconductor chip 200. In FIG. 11, the semiconductor package 1000 is illustrated as including five second semiconductor chips 200, but embodiments of the present disclosure are not limited thereto. For example, the semiconductor package 1000 may include two or more second semiconductor chips 200. For example, the semiconductor package 1000 may include a four-multiple number of second semiconductor chips 200. A plurality of second semiconductor chips 200 may be sequentially stacked on the first semiconductor chip 100. For convenience of description, a lowermost one of the second semiconductor chips 200 may be referred to as a lowermost second semiconductor chip 200L, and an uppermost one of the second semiconductor chip 200 may be referred to as an uppermost second semiconductor chip 200H.

The first semiconductor chip 100 and the plurality of second semiconductor chips 200 each included in the semiconductor package 1000 may be electrically connected to each other through a plurality of coupling pads 320, and thus, may transfer and receive a signal therebetween and may provide power and a ground. For example, the plurality of coupling pads 320 may be disposed between the first semiconductor chip 100 and the lowermost second semiconductor chip 200L and between each of two second semiconductor chips 200 adjacent to each other.

For example, the plurality of coupling pads 320 may include a material including Cu. A coupling pad 320 disposed between the first semiconductor chip 100 and the lowermost second semiconductor chip 200L may be referred to as a first coupling pad, and a coupling pad 320 disposed between two second semiconductor chips 200 adjacent to each other may be referred to as a second coupling pad.

The first semiconductor chip 100 may include a first semiconductor substrate 110 including an active surface and an inactive surface which are opposite to each other, a first semiconductor device 112 formed on the active surface of the first semiconductor substrate 110, a first wiring structure 130 formed on the active surface of the first semiconductor substrate 110, and a plurality of first through vias 120 which are connected to the first wiring structure 130 and pass through at least a portion of the first semiconductor chip 100. The first semiconductor chip 100 may further include a plurality of chip pads 150 which are disposed on a lower surface thereof and are electrically connected to a first wiring pattern 132 and/or a first wiring via 134 of the first wiring structure 130. The plurality of chip pads 150 may be electrically connected to the first semiconductor device 112, the first wiring pattern 132, and/or the first wiring via 134.

In the semiconductor package 1000, the first semiconductor chip 100 may be disposed so that the active surface of the first semiconductor substrate 110 faces a lower side and the inactive surface thereof faces an upper side. Accordingly, unless separately described, an upper surface of the first semiconductor chip 100 included in the semiconductor package 1000 may be referred to as a side which faces away from the inactive surface of the first semiconductor substrate 110, and a lower surface of the first semiconductor chip 100 may be referred to as a side which faces away from the active surface. On the other hand, when described with respect to the first semiconductor chip 100, a lower surface of the first semiconductor chip 100 facing in a same direction as a facing direction of the active surface of the first semiconductor substrate 110 may be referred to as a front-side surface of the first semiconductor chip 100, and an upper surface of the first semiconductor chip 100 facing in a same direction as a facing direction of the inactive surface of the first semiconductor substrate 110 may be referred to as a backside surface of the first semiconductor chip 100.

The second semiconductor chips 200 may include a second semiconductor substrate 210 including an active surface and an inactive surface which are opposite to each other, a second semiconductor device 212 formed on the active surface of the second semiconductor substrate 210, and a second wiring structure 230 formed on the active surface of the second semiconductor substrate 210.

At least some of the plurality of second semiconductor chips 200 may further include a plurality of second through vias 220 which are connected to the second wiring structure 230 and pass through at least a portion of the second semiconductor chip 200. In some embodiments, the uppermost second semiconductor chip 200H, which is a second semiconductor chip 200 disposed farthest away from the first semiconductor chip 100 and disposed at an uppermost end of the semiconductor package 1000, may not include the plurality of second through vias 220.

Only the second semiconductor substrate 210 may be exposed at an upper surface of the uppermost second semiconductor chip 200H. That is, only a semiconductor material may be disposed at the upper surface of the uppermost second semiconductor chip 200H.

In the semiconductor package 1000, each of the plurality of second semiconductor chips 200 may be sequentially stacked in the vertical direction (the Z direction) on the first semiconductor chip 100 so that the active surface thereof faces a lower side (i.e., the first semiconductor chip 100). Accordingly, unless separately described, an upper surface of the second semiconductor chip 200 included in the semiconductor package 1000 may be referred to as a side which faces in a same direction as the inactive surface of the second semiconductor substrate 210, and a lower surface of the second semiconductor chip 200 may be referred to as a side which faces in a same direction as the active surface of the second semiconductor substrate 210. On the other hand, when described with respect to the second semiconductor chip 200, a lower surface of the second semiconductor chip 200 that faces in a same direction as a facing direction of the active surface of the second semiconductor substrate 210 may be referred to as a front-side surface of the second semiconductor chip 200, and an upper surface of the second semiconductor chip 200 that faces in a same direction as a facing direction of the inactive surface of the second semiconductor substrate 210 may be referred to as a backside surface of the second semiconductor chip 200.

The first semiconductor substrate 110 and the second semiconductor substrate 210 may include, for example, a semiconductor material such as silicon (Si). Alternatively, the first semiconductor substrate 110 and the second semiconductor substrate 210 may include, for example, a semiconductor material such as germanium (Ge). Each of the first semiconductor substrate 110 and the second semiconductor substrate 210 may include an active surface and an inactive surface opposite to the active surface. The first semiconductor substrate 110 and the second semiconductor substrate 210 may each include a conductive region (e.g., an impurity-doped well). Each of the first semiconductor substrate 110 and the second semiconductor substrate 210 may have various device isolation structures such as a shallow trench isolation (STI) structure.

Each of the first semiconductor device 112 and the second semiconductor device 212 may include various kinds of a plurality of individual devices. The plurality of individual devices may include various microelectronic devices, and for example, may include metal-oxide-semiconductor field effect transistors (MOSFETs) such as complementary metal-oxide-semiconductor (CMOS) transistors, system large scale integration (LSI), image sensors such as CMOS imaging sensors (CISs), micro-electro-mechanical system (MEMS), active devices, and passive devices. The plurality of individual devices may be electrically connected to the conductive region of the first semiconductor substrate 110 or the second semiconductor substrate 210. Each of the first semiconductor device 112 and the second semiconductor device 212 may further includes a conductive wiring or a conductive plug, which electrically connects at least two of the plurality of individual devices or the plurality of individual devices to the conductive region of each of the first semiconductor substrate 110 and the second semiconductor substrate 210. Also, the plurality of individual devices may be electrically isolated from other individual devices adjacent thereto by an insulation layer.

At least one of the first semiconductor chip 100 and the second semiconductor chip 200 may be a memory semiconductor chip.

In some embodiments, the first semiconductor chip 100 may be a buffer chip which includes a serial-parallel conversion circuit and is for controlling the plurality of second semiconductor chips 200, and each of the plurality of second semiconductor chips 200 may be a memory chip including memory cells. For example, the semiconductor package 1000 including the first semiconductor chip 100 and the plurality of second semiconductor chips 200 may be a high bandwidth memory (HBM), the first semiconductor chip 100 may be referred to as an HBM control die, and each of the plurality of second semiconductor chips 200 may be referred to as a DRAM die.

The first wiring structure 130 may include a plurality of first wiring patterns 132, a plurality of first wiring vias 134 connected to the plurality of first wiring patterns 132, and a first inter-wiring insulation layer 136 surrounding the plurality of first wiring patterns 132 and the plurality of first wiring vias 134. In some embodiments, the plurality of first wiring patterns 132 may have a thickness of about 0.5 μm or less. In some embodiments, the first wiring structure 130 may have a multi-layer wiring structure including the first wiring patterns 132 and the first wiring via 134, which are disposed at different vertical levels.

The second wiring structure 230 may include a plurality of second wiring patterns 232, a plurality of second wiring vias 234 connected to the plurality of second wiring patterns 232, and a second inter-wiring insulation layer 236 surrounding the plurality of second wiring patterns 232 and the plurality of second wiring vias 234. In some embodiments, the plurality of second wiring patterns 232 may have a thickness of about 0.5 μm or less. In some embodiments, the second wiring structure 230 may have a multi-layer wiring structure including the second wiring patterns 232 and the second wiring via 234, which are disposed at different vertical levels.

The plurality of first wiring patterns 132, the plurality of first wiring vias 134, the plurality of second wiring patterns 232, and the plurality of second wiring vias 234 may include, for example, a metal material such as aluminum, copper, or tungsten. In some embodiments, the plurality of first wiring patterns 132, the plurality of first wiring vias 134, the plurality of second wiring patterns 232, and the plurality of second wiring vias 234 may each include a wiring barrier layer and a wiring metal layer. The wiring barrier layer may include metal, metal nitride, or an alloy. The wiring metal layer may include at least one metal selected from among tungsten (W), aluminum (Al), titanium (Ti), tantalum (Ta), ruthenium (Ru), manganese (Mn), and copper (Cu).

In a case where each of the first wiring structure 130 and the second wiring structure 230 is a multi-layer wiring structure, the first inter-wiring insulation layer 136 and the second inter-wiring insulation layer 236 may each have a multi-layer structure where a plurality of insulation layers are stacked, based on the multi-layer wiring structure of each of the first wiring structure 130 and the second wiring structure 230. For example, the first inter-wiring insulation layer 136 and the second inter-wiring insulation layer 236 may include silicon oxide, silicon nitride, silicon oxynitride, an insulating material having a dielectric constant which is less than that of silicon oxide, or a combination thereof. In some embodiments, the first inter-wiring insulation layer 136 and the second inter-wiring insulation layer 236 may include a tetraethyl orthosilicate (TEOS) layer or an ultra low-K (ULK) layer having an ultra low dielectric constant K of about 2.2 to about 2.4. The ULK layer may include a SiOC layer or a SiCOH layer.

Each of the first through via 120 and the second through via 220 may include a through silicon via (TSV). Each of the first through via 120 and the second through via 220 may include a conductive plug passing through each of the first semiconductor substrate 110 and the second semiconductor substrate 210 and a conductive barrier layer surrounding the conductive plug. The conductive plug may have a circular pillar shape, and the conductive barrier layer may have a cylindrical shape which surrounds a sidewall of the conductive plug. A via insulation layer may be disposed between the first through via 120 and the first semiconductor substrate 110 and between the second through via 220 and the second semiconductor substrate 210 and may surround sidewalls of the first through via 120 and the second through via 220. Each of the first through via 120 and the second through via 220 may include one from among a via-first structure, a via-middle structure, and a via-last structure.

A horizontal width of the first semiconductor chip 100 may be greater than a horizontal width of the second semiconductor chip 200. A vertical height of the first semiconductor chip 100 may be approximately equal to a vertical height of the second semiconductor chip 200.

The plurality of coupling pads 320 may be electrically connected to the plurality of first through vias 120 or the plurality of second through vias 220, which are disposed under the second wiring pattern 232 and/or the second wiring via 234 of the second wiring structure 230.

For example, the second wiring pattern 232 and/or the second wiring via 234 of the second wiring structure 230 included in the lowermost second semiconductor chip 200L may be electrically connected to the plurality of first through vias 120 included in the first semiconductor chip 100, disposed at a lower side, through a group of the coupling pads 320 (i.e., a plurality of first coupling pads), and the second wiring pattern 232 and/or the second wiring via 234 of the second wiring structure 230 included in the second semiconductor chips 200, other than the lowermost second semiconductor chip 200L, may be electrically connected to the plurality of second through vias 220 included in an adjacent, lower one from among the second semiconductor chips 200 through another group of the coupling pads 320 (i.e., a plurality of second coupling pads).

The plurality of coupling pads 320 may be surrounded by a chip coupling insulation layer 300, between the first semiconductor chip 100 and the plurality of second semiconductor chips 200, namely, between the first semiconductor chip 100 and the lowermost second semiconductor chip 200L, and between each of two adjacent ones of the second semiconductor chips 200. The plurality of coupling pads 320 may pass through the chip coupling insulation layer 300. Each of a plurality of chip coupling insulation layers 300 may be disposed between the first semiconductor chip 100 and the plurality of second semiconductor chips 200.

After conductive material layers is separately and respectively formed on surfaces where the first semiconductor chip 100 faces two adjacent ones of the second semiconductor chips 200, the conductive material layers facing each other may be expanded by heat, and diffusion bonding may be performed on the conductive material layers so that the conductive material layers are provided as one body through diffusion of metal atoms contacting each other and included therein, thereby forming each of the plurality of coupling pads 320.

After insulating material layers is separately and respectively formed on surfaces where the first semiconductor chip 100 faces two adjacent ones of the second semiconductor chips 200, the insulating material layers facing each other may be expanded by heat in a process of forming the plurality of coupling pads 320, and diffusion bonding may be performed on the insulating material layers so that the insulating material layers are provided as one body through diffusion of atoms contacting each other and included therein, thereby forming the chip coupling insulation layer 300.

A lowermost chip coupling insulation layer 300L, disposed between the first semiconductor chip 100 and the lowermost second semiconductor chip 200L, from among the plurality of chip coupling insulation layers 300 may be formed through diffusion bonding on an insulating material layer covering an upper surface of the first semiconductor chip 100 and an insulating material layer covering a lower surface of the lowermost second semiconductor chip 200L.

The chip coupling insulation layers 300, other than the lowermost chip coupling insulation layer 300L, may cover all of an upper surface and a lower surface of the second semiconductor chips 200 facing each other along with the plurality of coupling pads 320. The chip coupling insulation layers 300 may include an upper surface and a lower surface, which are flat to have approximately the same thickness.

The chip coupling insulation layers 300, other than the lowermost chip coupling insulation layer 300L, may overlap the plurality of second semiconductor chips 200 in the vertical direction (the Z direction). The chip coupling insulation layers 300 and a side surface of each of the plurality of second semiconductor chips 200 may be aligned with each other in the vertical direction to configure a coplanar surface.

The chip coupling insulation layer 300 may include at least one from among SiO, SiN, SiCN, SiCO, and a polymer material. The polymer material may be benzocyclobutene (BCB), polyimide (PI), polybenzoxazole (PBO), silicone, acrylate, or epoxy. For example, the chip coupling insulation layer 300 may include silicon oxide. In some embodiments, the chip coupling insulation layers 300 may include the same material. The chip coupling insulation layers 300 may have, for example, a thickness of about 100 nm to about 1 μm.

The semiconductor package 1000 may further include a package molding layer 400 which covers an upper surface of the first semiconductor chip 100 and surrounds side surfaces of the plurality of second semiconductor chips 200, on the first semiconductor chip 100. The package molding layer 400 may include, for example, an epoxy mold compound (EMC).

In some embodiments, the semiconductor package 1000 may further include a package redistribution layer 500 disposed on a lower surface of the first semiconductor chip 100. The package redistribution layer 500 may include a plurality of package redistribution line patterns 520, a plurality of package redistribution vias 540, and a package redistribution insulation layer 560. In some embodiments, the package redistribution insulation layer 560 may be provided in plural, and the plurality of package redistribution insulation layers 560 may be stacked. The package redistribution insulation layer 560 may be formed from, for example, photo imageable dielectric (PID) or photosensitive polyimide (PSPI). The package redistribution line pattern 520 and the package redistribution via 540 may include, for example, metal such as copper (Cu), aluminum (Al), tungsten (W), titanium (Ti), tantalum (Ta), indium (In), molybdenum (Mo), manganese (Mn), cobalt (Co), zinc (Sn), nickel (Ni), magnesium (Mg), rhenium (Re), beryllium (Be), gallium (Ga), or ruthenium (Ru), or an alloy thereof, but are not limited thereto. In some embodiments, the package redistribution line pattern 520 and the package redistribution via 540 may be formed by stacking metal or an alloy of metals on a seed layer including titanium, titanium nitride, or titanium tungsten.

The plurality of package redistribution line patterns 520 may be disposed on at least one from among an upper surface and a lower surface of the package redistribution insulation layer 560. The plurality of package redistribution vias 540 may pass through the package redistribution insulation layer 560 and may respectively contact and be connected to some of the plurality of package redistribution line patterns 520. In some embodiments, at least some of the plurality of package redistribution line patterns 520 may be formed along with some of the plurality of package redistribution vias 540, and thus, may configure one body. For example, the package redistribution line pattern 520 and the package redistribution via 540 contacting an upper surface of the package redistribution line pattern 520 may be configured as one body. The package redistribution insulation layer 560 may surround the plurality of package redistribution line patterns 520 and the plurality of package redistribution vias 540.

The plurality of package redistribution line patterns 520 and the plurality of package redistribution vias 540 may be electrically connected to the plurality of chip pads 150. In some embodiments, at least some of the plurality of package redistribution vias 540 may contact the plurality of chip pads 150. For example, when the package redistribution layer 500 includes a plurality of package redistribution insulation layers which are stacked, the package redistribution via 540 passing through an uppermost one of the package redistribution insulation layers may contact and electrically be connected to the chip pad 150.

In some embodiments, the plurality of package redistribution vias 540 may have a tapered shape where a horizontal width narrows and extends from a lower side to an upper side. That is, the plurality of package redistribution vias 540 may progressively distance from the first semiconductor chip 100 and may increase in horizontal width.

A package redistribution line pattern 520, disposed on a lower surface of the package redistribution layer 500, may be referred to as a package pad 550. A plurality of package connection terminals 600 may be attached on a plurality of package pads 550. For example, the package connection terminal 600 may be a solder ball or a bump.

In some embodiments, the semiconductor package 1000 may not include the package redistribution layer 500. For example, the plurality of package connection terminals 600 may be attached on the plurality of chip pads 150.

A horizontal width and a horizontal area of the package redistribution layer 500 may have the same as a horizontal width and a horizontal area of the first semiconductor chip 100. The package redistribution layer 500 and the first semiconductor chip 100 may overlap with each other in the vertical direction.

For example, horizontal widths and horizontal areas of the package redistribution layer 500, the first semiconductor chip 100, and the package molding layer 400 may be substantially the same as each other. Side surfaces of the package redistribution layer 500, the first semiconductor chip 100, and the package molding layer 400 may be aligned with one another in the vertical direction to configure a coplanar surface.

In the semiconductor package 1000 according to an embodiment, the first semiconductor chip 100 and the plurality of second semiconductor chips 200 may be stacked and formed by hybrid bonding where the plurality of coupling pads 320 and the chip coupling insulation layer 300 are formed through diffusion bonding. The first semiconductor chip 100 and the plurality of second semiconductor chips 200 may each include the second pad 40, and thus, whether the first pad 30 thereof is defective may be easily determined. Accordingly, a hybrid bonding process having high reliability may be performed. The first semiconductor chip 100 and the plurality of second semiconductor chips 200 may each include the second pad 40, and thus, at least some of the plurality of coupling pads 320 may have a tetragonal cross-sectional shape. At least some of the plurality of coupling pads 320 may have a cross-sectional shape which differs from a cross-section shape of each of the first through via 120 and the second through via 220. For example, at least some of the plurality of coupling pads 320 may have a rectangular cross-sectional shape. For example, at least some of the plurality of coupling pads 320 may have a square cross-sectional shape. For example, at least some of the plurality of coupling pads 320 may be the first pads 30, and others of the plurality of the coupling pads 320 may be the second pads 40 (or the second pads 40a) described above with respect to FIGS. 1-10.

Non-limiting example embodiments of the present disclosure have been described in the drawings and the specification. Non-limiting example embodiments have been described by using the terms described herein, but these terms have been merely used for describing example embodiments and have not been used for limiting a meaning or limiting the scope of embodiments of the present disclosure. Therefore, it may be understood by those of ordinary skill in the art that various modifications and other equivalent embodiments may be implemented as a part of the present disclosure.

While non-limiting example embodiments of the present disclosure have been particularly shown and described, it will be understood that various changes in form and details may be made therein without departing from the spirit and scope of the following claims.

What is claimed is:

1. A semiconductor chip comprising:
a semiconductor substrate;
a plurality of through vias passing through at least a portion of the semiconductor substrate; and
a plurality of upper pads contacting the plurality of through vias,
wherein, in a plan view, each of the plurality of upper pads surround a respective one of the plurality of through vias, and
wherein at least one of the plurality of upper pads has a tetragonal cross-sectional shape.

2. The semiconductor chip of claim 1, wherein the plurality of upper pads comprise a first pad and a second pad, and
wherein the first pad and the second pad have shapes that are different from each other.

3. The semiconductor chip of claim 2, wherein, in the plan view, the first pad has a circular cross-sectional shape, and the second pad has a rectangular cross-sectional shape.

4. The semiconductor chip of claim 1, wherein, in the plan view, a distance from a sidewall of the at least one of the plurality of upper pads, having the tetragonal cross-sectional shape, to a center of the respective one of the plurality of through vias, that is surrounded by the at least one of the plurality of upper pads, is greater than a diameter of each of the plurality of through vias.

5. The semiconductor chip of claim 1, wherein an extension direction of each of a plurality of sidewalls of the semiconductor substrate is same as an extension direction of each of a plurality of sidewalls of the at least one of the plurality of upper pads having the tetragonal cross-sectional shape.

6. The semiconductor chip of claim 1, wherein, in the plan view, the semiconductor substrate comprises a center region and an edge region surrounding the center region, and
wherein the at least one of the plurality of upper pads having the tetragonal cross-sectional shape is in the edge region.

7. The semiconductor chip of claim 1, wherein the at least one of the plurality of upper pads having the tetragonal cross-sectional shape has a cross-sectional shape that is different from a cross-sectional shape of each of the plurality of through vias.

8. A semiconductor chip comprising:
a semiconductor substrate;
an upper insulation layer on an upper surface of the semiconductor substrate;
a lower insulation layer on a lower surface of the semiconductor substrate;
a plurality of through vias passing through at least a portion of the semiconductor substrate and the upper insulation layer; and
a plurality of upper pads surrounded by the upper insulation layer and contacting the plurality of through vias,
wherein, in a plan view, each of the plurality of upper pads surrounds a respective one of the plurality of through vias,
wherein the plurality of upper pads comprise a first pad and a second pad, and
wherein the second pad has a tetragonal cross-sectional shape.

9. The semiconductor chip of claim 8, wherein a ratio of half of a length of a sidewall of the second pad to a diameter of each of the plurality of through vias is about 1.5 or more.

10. The semiconductor chip of claim 8, wherein the semiconductor chip further comprises a first sidewall and a second sidewall, and the second pad comprises a third sidewall and a fourth sidewall,
wherein an extension direction of the first sidewall is the same as an extension direction of the third sidewall, and
wherein an extension direction of the second sidewall is the same as an extension direction of the fourth sidewall.

11. The semiconductor chip of claim 10, wherein a width of the third sidewall and a width of the fourth sidewall is within a range of 10 μm to 40 μm.

12. The semiconductor chip of claim 8, wherein a ratio of a diameter of the first pad to a diameter of each of the plurality of through vias is within a range of 1.5 to 2.5.

13. The semiconductor chip of claim 8, wherein the first pad and the second pad comprise a same material.

14. The semiconductor chip of claim 8, wherein a cross-sectional area of the first pad is less than a cross-sectional area of the second pad.

15. The semiconductor chip of claim 8, wherein the second pad has a rectangular cross-sectional shape.

16. The semiconductor chip of claim 8, wherein the second pad has a square cross-sectional shape.

17. A semiconductor package comprising:
a high bandwidth memory (HBM) control die having a first horizontal width, the HBM comprising:
a first semiconductor substrate comprising an active surface and an inactive surface that are opposite to each other; and
a plurality of through vias passing through at least a portion of the first semiconductor substrate;
a plurality of dynamic random-access memory (DRAM) dies each having a second horizontal width less than the first horizontal width and comprising a second semiconductor substrate comprising an active surface and an inactive surface that are opposite to each other, the active surface of the second semiconductor substrate being stacked on the HBM control die and facing the inactive surface of the first semiconductor substrate;
a plurality of coupling pads between the HBM control die and the plurality of DRAM dies;
a chip coupling insulation layer between the HBM control die and the plurality of DRAM dies to surround the plurality of coupling pads; and
a package molding layer on an upper surface of the HBM control die and side surfaces of the plurality of DRAM dies,
wherein the plurality of coupling pads comprises a first coupling pad and a second coupling pad, and
wherein the second coupling pad has a tetragonal cross-sectional shape.

18. The semiconductor package of claim 17, wherein the second coupling pad contacts a dummy through via of the plurality of DRAM dies.

19. The semiconductor package of claim 17, wherein a shape of a cross-sectional surface of each of the plurality of through vias is the same as a shape of a cross-sectional surface of the first coupling pad, and
wherein the shape of the cross-sectional surface of each of the plurality of through vias is different from a shape of a cross-sectional surface of the second coupling pad.

20. The semiconductor package of claim 17, wherein the plurality of coupling pads each comprise a material comprising copper (Cu), and
wherein the at least one chip coupling insulation layer comprises silicon oxide.
